(19) United States
(12) Patent Application Publication
(10) Pub. No.: US 2015/0279572 A1
(43) Pub. Date: Oct. 1, 2015

(54) SOLID-STATE DYE-DENSITIZED SOLAR CELL WITH LONG-TERM STABILITY CONTAINING PYRIDINE-BASED ADDITIVE

(71) Applicants: Hyundai Motor Company, Seoul (KR); Postech Academy-Industry Foundation, Pohang (KR)

(72) Inventors: Yong Jun Jang, Seongnam (KR); Sol Kim, Seoul (KR); Sang Hak Kim, Seoul (KR); Young Soo Kwon, Pohang (KR); Tai Ho Park, Pohang (KR)

(21) Appl. No.: 14/571,581

(22) Filed: Dec. 16, 2014

(30) Foreign Application Priority Data
Mar. 31, 2014 (KR) 10-2014-0037878

(51) Int. Cl. H01G 9/20; H01L 51/00

(52) U.S. Cl. CPC H01G 9/2009; H01G 9/2022; H01G 9/2031; H01G 9/2059; H01L 51/0067; H01L 51/0086; H01L 51/0077; H01L 51/006; H01L 51/0036; H01L 51/0056

(57) ABSTRACT

Disclosed is a solid-state dye-sensitized solar cell with improved long-term stability containing a pyridine-based compound as an additive. In particular, the solid-state dye-sensitized solar cell includes a hole transport layer containing a pyridine-based additive mixed with a hole transport material to provide a solid-state hole transport layer in the solid-state dye-sensitized solar cell. Accordingly, superior initial efficiency and substantially improved long-term stability of the solid-state dye-sensitized solar cell may be obtained. Further, the dye-sensitized solar cell may be manufactured using a simple process without using a sealing agent.

### CROSS-REFERENCE TO RELATED APPLICATION

This application claims under 35 U.S.C. §119(a) the benefit of Korean Patent Application No. 10-2014-0037878 filed on Mar. 31, 2014, the entire contents of which are incorporated herein by reference.

### TECHNICAL FIELD

The present invention relates to a solid-state dye-sensitized solar cell containing a pyridine-based additive for long-term stability. In particular, the solid-state dye-sensitized solar cell may includes a hole transport material matrix element containing a pyridine-based compound as additive in a solid hole transport layer of the solid-state dye-sensitized solar cell, and accordingly superior initial efficiency and significantly improved long-term stability may be obtained, and the solid-state dye-sensitized solar cell may be manufactured using a simple process without using a sealing agent.

### BACKGROUND

Recently, with the raising concerns over environment due to the depletion of fossil fuels and the greenhouse effect, interests in new and renewable energy capable of replacing fossil fuels have been increasing, and solar energy may be an alternative resource together with wind power, water power, tidal power energy, and the like.

In particular, solar cells for utilizing solar energy have been widely developed, and among these, inorganic solar cells using silicon directly convert photons to electricity. However, these inorganic solar cells may not be cost-competitiveness due to the high unit costs compared to other types of powerplants. On the other hand, dye-sensitized solar cells have been receiving much attention due to their advantages such as substantial power conversion efficiency and low unit costs of production.

In the related arts, the dye-sensitive solar cells may be formed with 5 materials including 1) a conductive substrate, 2) a semiconductor film, 3) a dye (light-sensitive material), 4) an electrolyte, and 5) a counter electrode, and the efficiency of dye-sensitive solar cells may be determined by the compatibility and the optimization between those materials.

The energy conversion system of such dye-sensitive solar cells may be explained by the mechanism of the following Reaction Formulae 1 to 6.

In particular, a dye (S_{ads}) adsorbed to a semiconductor oxide may be excited by light (Reaction Formula 1), and electrons may be injected to a conduction band of the oxide (Reaction Formula 2). The oxidized dye may be reduced again by receiving electrons from an electrolyte including oxidation and reduction species (R/R⁻) (Reaction Formula 3). The injected electrons may flow through an external circuit along the semiconductor network and reach a counter electrode. In the counter electrode, the oxidation and reduction species may be regenerated and complete the circuit. A device may form a repetitive and stable photoelectric energy conversion system under the closed external circuit and light irradiation. However, unwanted reactions that deteriorate the efficiency of a device may occur, for example, a reaction in which the injected electrons are recombined with the oxidized dye (Reaction Formula 5), or recombined with the oxidized oxidation and reduction species on the TiO₂ surface (Reaction Formula 6).

S_{ads}+hv→S*_{ads} (Reaction Formula 1)

S*_{ads}→S⁺_{ads}+e⁻ᵢₙⱼ Reaction Formula 2)

S⁺_{ads}+R⁻→S_{ads}+R (Reaction Formula 3)

R+e⁻_{cathode}→R⁻_{cathode} (Reaction Formula 4)

e⁻ᵢₙⱼ+S⁺_{ads}→S_{ads} (Reaction Formula 5)

e⁻ᵢₙⱼ+R→R⁻_{anode} (Reaction Formula 6)

The first efficient dye-sensitive solar cell was reported in 1991 by a team of professor Gratzel in Swiss, and by using a dye capable of absorbing light, and TiO₂, a nanocrystalline inorganic semiconductor oxide capable of supporting large amounts of the dye. A photoelectric conversion efficiency of about 7% or greater was accomplished. Through substantial developments thereafter, currently liquid electrolyte-based dye-sensitive solar cells may have efficiency of about 11% or greater. However, in liquid electrolyte-based dye-sensitive solar cells, solvents may evaporate or leakage thereof may occur, and a counter electrode may be corroded by using iodide as oxidation and reduction species. Accordingly, methods of using solid-state organic and inorganic hole transport materials have been studied in order to solve such problems.

In addition, all-solid-state dye-sensitive solar cells have received much attention since about a decade ago. For example, flexible solar cells may be manufactured using a roll-to-roll process. In 1998, an all-solid-state dye-sensitive solar cell using a monomolecular hole transport material named spiro-OMeTAD was developed but the efficiency thereof was about 0.1% or lower. Since then, however, maximum efficiency have been continuously reported up to date through dye development, surface modification, doping material development, device structure optimization and the like.

In the related arts, perovskite nanocrystalline particles having lead, a halogen element and methyl amine as used in the dye sensitive solar cells have been reported to exhibit substantial efficiency due to the properties of strong absorption over a wide light wavelength range while being used as a light absorbing material or a dye. A team of professor PARK, Namkyu in Korea and the Korea Research Institute of Chemical Technology have accomplished photoelectric conversion efficiency of about 12% or greater by introducing various hole transport materials to perovskite nanocrystals. In addition, a team of professor Gratzel in Swiss has been reported a solid-state dye-sensitized solar cell with super-high efficiency of about 15%. Accordingly, various methods for commercialization based on such high efficiency are expected to follow. However, although solid-state dye-sensitized solar cells use a solid-state hole transport material instead of a liquid electrolyte, long-term stability may deteriorate due to tertiary-butylpyridine (tBP) and lithium bis(trifluoromethanesulfonyl)imide (Li-TFSI), which are materials required as an additive. For example, tBP is a liquid additive and volatile thereby not being suitable to use as an additive in the long term.

In addition, Li-TFSI, a representative additive, is mixed to a hole transport material and doping the hole transport material, and is effective in improving electrical conductivity and suppressing a hole-electron recombination reaction on an oxide electrode surface. tBP increases a conduction band by being located on the electrode surface of a semiconductor oxide thereby effectively improving the open-circuit voltage of solar cell devices. Long-term stability of solid-state dye-sensitized solar cells may be improved when the role of these two additives are consistently maintained. Nevertheless, research papers and patents on long-term stability by additives have not been published.

In addition, in the related arts, a photoelectric conversion device has been developed. The device includes a pair of electrodes, and a solid layer formed with a charge transportable heterocylic polymer provided between the pair of electrodes and the solid layer contains a hole transportable heterocylic polymer and fullerene derivatives. Moreover, in other example, a 2,2-bipyridine ligand, a sensitive dye and a dye-sensitive solar cell, and a dye-sensitive solar cell including a polypyridyl complex of Ru, Os or Fe and the like as a photosensitizing dye have been introduced. Further, a semi-solid polymer electrolyte for a dye-sensitive solar cell, a hole transport material included therein, and a dye-sensitive solar cell including the electrolyte have been reported and as a semi-solid polymer electrolyte, acetotnitrile, LiI, I₂, 1,2-dimethyl-3-propylimidazolium iodide (DMPII) and 4-tert-butylpyridine (tBP) are included as a liquid electrolyte. A solar cell using a metal phthalocyanine complex as a sensitizing dye of an optical transducer and containing a polymer having a 2,6-diphenylphenoxy group with an alkyl or an alkoxy group in a solid hole transport layer has been also provided.

Such developments of solar cell qualities and effects, however, have not been able to solve a problem of durability such as long-term stability.

The above information disclosed in this Background section is only for enhancement of understanding of the background of the invention and therefore it may contain information that does not form the prior art that is already known in this country to a person of ordinary skill in the art.

### SUMMARY OF THE INVENTION

In a preferred aspect, the present invention provides a solar cell with improved long term stability. When a pyridine-based compound is used as an additive, a hole transport layer may be in a solid-state such that a solid-state dye-sensitized solar cell may be obtained to have superior initial efficiency and substantially improved long-term stability. Further, the solar cell may be manufactured using a simple process without a sealing agent and the like.

In one aspect, provided is a novel solid-state dye-sensitized solar cell that contains a pyridine-based compound as an additive in a hole transport layer. In particular, the hole transport layer may be in a solid-state.

In another aspect, provided is a solid-state dye-sensitized solar cell with improved long-term stability while maintaining superior initial efficiency by using a pyridine-based compound as an additive in a solid-state hole transport layer.

In addition, the present invention provides a method for manufacturing a solid-state dye-sensitized solar cell using a simple manufacturing process without using a sealing agent and the like.

In an exemplary embodiment, the solid-state dye-sensitized solar cell with improved long-term stability may contain a pyridine-based compound as additive. In particular, the solar cell may include, in a hole transport layer, one or more pyridine compounds independently selected from compounds of the following Chemical Formulae 1 to 3 as an additive.

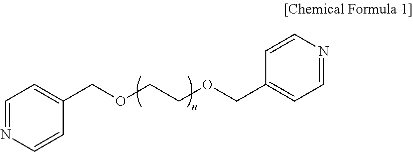

In the Chemical Formula 1, n may be a natural number ranging from 1 to 20.

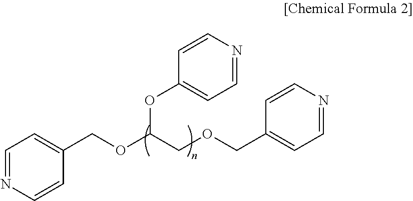

In the Chemical Formula 2, n may be a natural number ranging from 1 to 10.

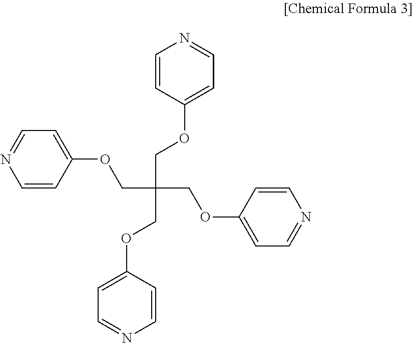 [SMILES: c1cc(OCC(COc2ccncc2)(COc2ccncc2)COc2ccncc2)ccn1]

In an exemplary embodiment, the method may include: preparing a mixed solution of a hole transport material by dissolving a hole transport material in a solvent and adding one or more pyridine compounds independently selected from compounds of the Chemical Formulae 1 to 3 thereto; forming an inorganic oxide dense layer on a working electrode; forming a light absorbing layer including a porous oxide and a light absorbing dye on the inorganic oxide dense layer; forming a hole transport layer by applying the mixed solution of the hole transport material on the light absorbing layer; and applying a counter electrode on the hole transport layer.

Further provided are vehicles that comprise the solar cell as described herein.

Other aspects and various exemplary embodiments of the invention are discussed infra.

As described above, a solid-state dye-sensitized solar cell with improved long-term stability may contain a pyridine-based compound as an additive to a solid hole transport material, thereby significantly improving long-term stability while having equal initial efficiency compared to existing solid-state dye-sensitized solar cells.

In addition, the solid dye-sensitive solar cell may be manufactured efficiently by simplifying the manufacturing process since a sealing agent that has been used for improving long-term stability may not be required due to the use of a pyridine-based additive in a hole transport layer during the manufacturing process.

### BRIEF DESCRIPTION OF THE DRAWINGS

The above and other features of the present invention will now be described in detail with reference to certain exemplary embodiments thereof illustrated the accompanying drawings which are given hereinbelow by way of illustration only, and thus are not limitative of the present invention, and wherein:

FIG. 1 illustrates a cross-sectional structure of an exemplary solid dye-sensitive solar cell manufactured according to an exemplary embodiment of the present invention; and

FIG. 2 shows an exemplary graph of photoelectric conversion efficiency of time course in exemplary solar cells prepared in the examples according to exemplary embodiments of the present invention and comparative example.

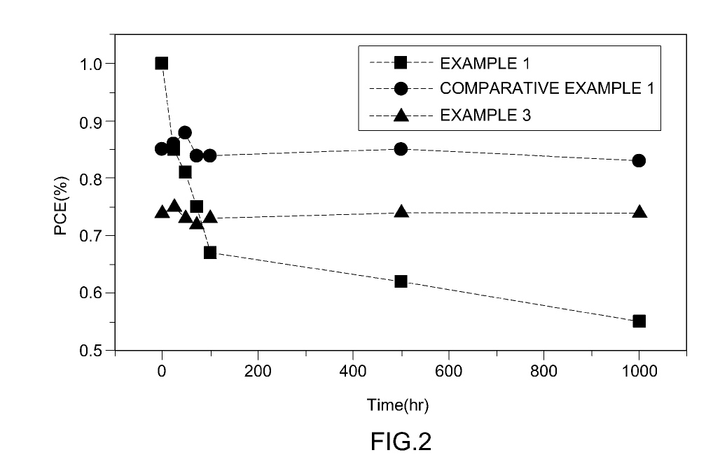

It should be understood that the appended drawings are not necessarily to scale, presenting a somewhat simplified representation of various preferred features illustrative of the basic principles of the invention. The specific design features of the present invention as disclosed herein, including, for example, specific dimensions, orientations, locations, and shapes will be determined in part by the particular intended application and use environment.

In the figures, reference numbers refer to the same or equivalent parts of the present invention throughout the several figures of the drawing.

10: Solar Cell
11: Working Electrode (First Electrode)
12: Inorganic Oxide Dense Layer
13: Light Absorbing Layer of Porous Oxide and Light Absorbing dye
14: Hole Transport Layer
15: Counter Electrode (Second Electrode)

### DETAILED DESCRIPTION

It is understood that the term “vehicle” or “vehicular” or other similar term as used herein is inclusive of motor vehicles in general such as passenger automobiles including sports utility vehicles (SUV), buses, trucks, various commercial vehicles, watercraft including a variety of boats and ships, aircraft, and the like, and includes hybrid vehicles, electric vehicles, plug-in hybrid electric vehicles, hydrogen-powered vehicles and other alternative fuel vehicles (e.g. fuels derived from resources other than petroleum). As referred to herein, a hybrid vehicle is a vehicle that has two or more sources of power, for example both gasoline-powered and electric-powered vehicles.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof. As used herein, the term “and/or” includes any and all combinations of one or more of the associated listed items.

Unless specifically stated or obvious from context, as used herein, the term “about” is understood as within a range of normal tolerance in the art, for example within 2 standard deviations of the mean. “About” can be understood as within 10%, 9%, 8%, 7%, 6%, 5%, 4%, 3%, 2%, 1%, 0.5%, 0.1%, 0.05%, or 0.01% of the stated value. Unless otherwise clear from the context, all numerical values provided herein are modified by the term “about”.

Hereinafter reference will now be made in detail to various embodiments of the present invention, examples of which are illustrated in the accompanying drawings and described below. While the invention will be described in conjunction with exemplary embodiments, it will be understood that present description is not intended to limit the invention to those exemplary embodiments. On the contrary, the invention is intended to cover not only the exemplary embodiments, but also various alternatives, modifications, equivalents and other embodiments, which may be included within the spirit and scope of the invention as defined by the appended claims.

The present invention provides a solid-state dye-sensitized solar cell with improved long-term stability containing a pyridine-based compound as an additive. In particular, the solar cell may include, in a hole transport layer, one or more pyridine compounds independently selected from compounds of the following Chemical Formulae 1 to 3 as an additive.

[Chemical Formula 1] may be presented as follows:

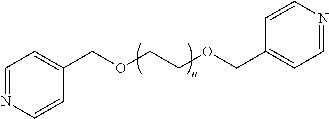

In the Chemical Formula 1, n may be a natural number ranging from 1 to 20.

[Chemical Formula 2] may be presented as follows:

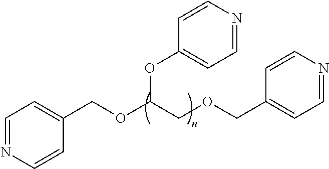

In the Chemical Formula 2, n may be a natural number ranging from 1 to 10.

[Chemical Formula 3] may be presented as follows:

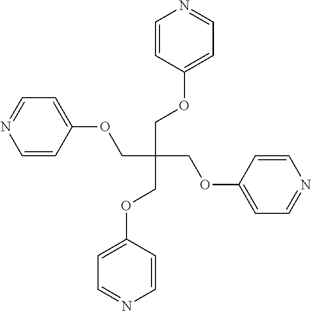 [SMILES: c1cc(OCC(COc2ccncc2)(COc2ccncc2)COc2ccncc2)ccn1]

The pyridine compound of Chemical Formula 1 may be a dimer having a long alkyl chain, and an exemplary dimer may be a compound of the following Chemical Formula 1a, where n is 1.

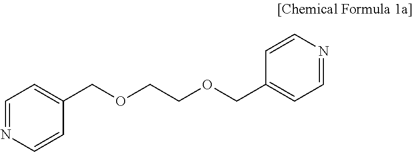 [SMILES: c1cc(COCCOCc2ccncc2)ccn1]

The pyridine compound of the Chemical Formula 2 is a multimer having a branched alkyl chain, and an exemplary multimer of the Chemical Formula 2 may be a compound of the following Chemical Formula 2a, where n is 1.

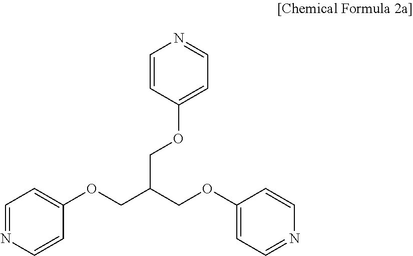 [SMILES: c1cc(OCC(COc2ccncc2)COc2ccncc2)ccn1]

The pyridine compound of the Chemical Formula 3 may be a tetramer compound and have a structure of the tetramer compound of Chemical Formula 2 in which, for example, n is 2.

According to exemplary embodiments of the present invention, the one or more pyridine compounds selected from the compounds of the Chemical Formulae 1 to 3 may form a solid-state hole transport layer as being mixed to a hole transport material as an additive.

The hole transport material forming a hole transport material matrix element may be added with the pyridine compounds. The hole transport material may include one or more selected from the group consisting of poly-hexylthiophene (P3HT), 2,2′,7,7′-tetrakis(diphenylamino)-9.9′-spirobifluorene (Spiro-MeOTAD), Poly[2-methoxy-5-(2-ethylhexyloxy)-1,4-phenylenevinylene] (MEHPPV), Poly[2,5-bis(2-decyldodecyl)pyrrolo[3,4-c]pyrrole-1,4(2H,5H)-dione-(E)-1,2-di(2,2′-bithiophen-5-yl)ethene] (PDPPDBTE) and the like. In particular, the hole transport material in the solid-state hole transport layer may be present in a solid state.

The pyridine compound of Chemical Formulae 1 to 3 may be included in a concentration of about 0.05 to 0.5 M, or particularly in a concentration of about 0.05 to 0.3 M based on the solid-state hole transport material.

The pyridine compound of the Chemical Formula 1 may be included in a concentration of about 0.1 to 0.3 M based on the solid-state hole transport material.

In addition, the pyridine compound of the Chemical Formula 2a may be included in a concentration of about 0.05 to 0.2 M based on the solid-state hole transport material.

Moreover, the pyridine compound of the Chemical Formula 3 may be included in a concentration of about 0.05 to 0.1 M based on the solid-state hole transport material.

When the pyridine-based additive is included in greater than about 0.5 M, the rapid decrease of short-circuit current in solar cell devices and phase separation inside a hole transport layer may occur.

Further, lithium bis(trifluoromethanesulfonyl)imide (Li-TFSI) may be further mixed to the hole transport layer in addition to P3HT or Spiro-MeOTAD as the hole transport material and the pyridine compounds of Chemical Formulae 1 to 3 as the additive.

The Li-TFSI may be included in a concentration of about 5 to 30 mM based on the solid-state hole transport material.

The solid dye-sensitive solar cell according to an exemplary embodiment of the present invention may have a structure including: a working electrode configured to be a first electrode; a second electrode configured to be provided opposite to the first electrode; an oxide layer configured to be formed between the first electrode and the second electrode and comprise a light absorbing layer including porous oxide and light absorbing dye; and a hole transport layer configured to be adjacent to the oxide layer and contain a hole transport material and one or more pyridine compounds selected from the compounds of the Chemical Formulae 1 to 3 as an additive.

In addition, a mixed solution of a hole transport material is provided to form a hole transport layer as described above.

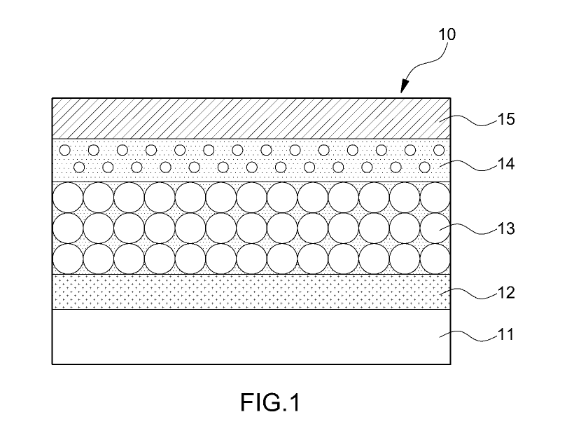

In an exemplary embodiment, the solid-state dye-sensitized solar cell having improved long-term stability may contain a pyridine-based compound as an additive and have a structure as illustrated in FIG. 1.

As a constitution of each layer forming a solar cell (10), FIG. 1 illustrates a cross-sectional structure of a solar cell (10). An inorganic oxide dense layer (12) may be formed on a first electrode (11) that is a working electrode, and a light absorbing layer (13) of porous oxide and light absorbing dye may be formed on the inorganic oxide dense layer (12), a hole transport layer (14) may be formed on the light absorbing layer (13), and a second electrode (15) as a counter electrode may be formed on the hole transport layer (14).

In an exemplary embodiment, the solid-state dye-sensitized solar cell with improved long-term stability containing a pyridine-based additive may be. The method of manufacturing may include steps of: preparing a mixed solution of a hole transport material by dissolving a hole transport material in a solvent and adding one or more pyridine compounds selected from the compounds of the Chemical Formulae 1 to 3 thereto; forming an inorganic oxide dense layer on a working electrode; forming a light absorbing layer including a porous oxide and a light absorbing dye on the inorganic oxide dense layer; forming a hole transport layer by applying the mixed solution of the mixed solution of the hole transport material above to the light absorbing layer; and applying a counter electrode on the hole transport layer.

The first electrode may be a working electrode and may include one or more materials selected from the group consisting of indium-tin oxide (ITO), fluorine-doped tin oxide (FTO), ZnO/Ga₂O₃, ZnO/Al₂O₃ and SnO₂—Sb₂O₃.

The second electrode may be a counter electrode and may include gold, silver, platinum or the like.

The oxide layer provided between the first electrode and the second electrode may include the inorganic oxide dense layer and the light absorbing layer of porous oxide and light absorbing dye.

The inorganic oxide dense layer may include oxides such as titanium oxide and zinc oxide.

Further, the light absorbing layer may include the porous oxide and the light absorbing dye. The porous oxides may be porous titanium oxide zinc oxide, niobium oxide, aluminum oxide and the like and the dyes may be N719 and Z907 that are ruthenium-based dyes, cobalt-based complex dyes, organic dyes (3-(5-(4-(diphenylamino)styryl)thiophen-2-yl)-2-cyanoacrylicacid, D5) and methylammonium lead iodide having a perovskite structure. In particular, the dyes may be adsorbed to the porous oxides to absorb a light, thereby forming the light absorbing layer.

As described above, in order to improve the long-term stability of a solid-state dye-sensitized solar cell, one or more pyridines in the pyridine-based compound of the invention is provided. In particular, pyridines may be linked to each of pyridines through an alkyl or alkoxy chain. Accordingly, the compounds of dimer, trimer and tetramer of pyridines having increased linking numbers of 2, 3 and 4, respectively, or multimer compounds having higher linking numbers may be provided. As a result, liquid-state tBP may be changed into a semi-solid state and a solid state while maintaining the role of original tBP, when the pyridine-based compounds of the invention is added thereto as an additive.

By using the pyridine compounds as described above to a solid hole transport layer as an additive, the long-term stability of a dye-sensitive solar cell may be substantially improved.

In addition, the present invention may provide a solid-state dye-sensitized solar cell and a manufacturing method of the solid-state dye-sensitized solar cell such that economic feasibility may be improved using a simplified device manufacturing process by improving durability and without using a sealing process that may be a most expensive process in a dye-sensitive solar cell commercialization process.

### EXAMPLES

The following examples illustrate the invention and are not intended to limit the same.

### Example 1

2,2′,7,7′-tetrakis(diphenylamino)-9.9′-spirobifluorene (spiro-MeOTAD), a hole transport material, was dissolved in a chlorobenzene solvent to have a concentration of about 0.17 M, and as an additive, lithium bis(trifluoromethanesulfonyl)imide (Li-TFSI) and a dimer linking 2 pyridines were dissolved in the prepared spiro-MeOTAD solution to have concentrations of about 21 mM and about 0.11 M, respectively, for about 1 hour at a temperature of about 60° C. Therefore, a uniform and transparent solution was prepared.

A solution including a titanium precursor of titanium diisopropoxide bis(acetylacetonate) was dissolved in ethanol to have a concentration of about 0.2 M and then was applied on an indium-doped tin oxide transparent substrate to a thickness of about 50 nm using a spray pyrolysis method to form a titanium oxide dense layer. A solution including titanium oxide particles having particle diameters of about 20 nm dispersed was applied to the titanium oxide dense layer using a doctor blade method, and then a porous titanium oxide film having a thickness of about 2 μm was prepared through a thermal forming process for about 30 minutes at a temperature of about 450° C. The prepared film was immersed in a about 20 mM titanium chloride (TiCl₄) solution for about 30 minutes at a temperature of about 60° C., then washed with water and ethanol again, and thermal forming processes were repeated. Subsequently, the film was taken out at a temperature of about 80° C., and immersed in a solution into which Z907 (cis-disothiocyanato-(2,2′-bipyridyl-4,4′-dicarboxylic acid)-(2,2′-bipyridyl-4,4′-dinonyl) ruthenium(II)), a ruthenium-based dye, was dispersed in about 0.3 mM of acetotnitrile/butanol solvent for the dye to be adsorbed for about 12 hours. Then, the porous titanium oxide thick film to which the dye was adsorbed was washed with acetotnitrile and dried, and a working electrode in which a light absorbing layer was formed was prepared.

The mixed solution of a hole transport material prepared above was applied using a spin coating method to transport holes to the working electrode, and about 50 μl of the mixed solution was introduced to the working electrode using a pipette, and then spin coated for about 30 seconds at a speed of about 2000 rpm. The hole transport layer applied on the working electrode has a thickness of about 100 to 150 nm.

In order to complete the manufacture of a solid-state dye-sensitized solar cell device, an active layer area was selectively exposed to the prepared light absorption layer-hole transport layer working electrode using a film patterned with a mask, and a counter electrode having a thickness of about 100 nm was applied by thermal depositing gold on the exposed area under a vacuum of about 10⁻⁶ torr, and as a result, a solar cell was manufactured.

For the manufactured solar cell, short-circuit current density (J_{SC}), open-circuit voltage (V_{OC}), fill factor (FF), and photoelectric conversion efficiency (η) were measured, and long-term stability was tested for about 1000 hours under conditions of room temperature and a temperature of about 70° C. The results are shown in the following Table 1 and FIG. 1.

TABLE 1

| Storage | Storage | J_{SC} | | | |
|---|---|---|---|---|---|
| Temperature | Time | (mA/cm²) | V_{OC} (V) | FF (%) | η (%) |
| Room | 0 hours | 9.5 | 0.76 | 54.8 | 4.0 |
| Temperature | 500 hours | 9.2 | 0.80 | 53.1 | 3.9 |
| | 1000 hours | 9.2 | 0.81 | 52.4 | 3.9 |
| 70 °C. | 0 hours | 9.5 | 0.76 | 54.8 | 4.0 |
| | 500 hours | 9.1 | 0.79 | 55.0 | 4.1 |
| | 1000 hours | 9.2 | 0.81 | 49.8 | 3.7 |

### Example 2

A mixed solution of a hole transport material was prepared as described in Example 1.

A method for preparing a working electrode was described in Example 1, however, a CH₃NH₃Pb₃ nanocrystalline material was applied as a light absorbing material instead of Z907. The light absorber application was carried out using a method of spin coating a solution in which CH₃NH₃PbI₃ was dissolved in γ-butyrolactone in a about 40% weight ratio, and the solvent was completely dried by drying the spin coated light absorption layer for about 15 minutes at a temperature of about 100° C. Herein, a titanium oxide thick film was prepared to have a thickness of about 500 nm when manufacturing a solar cell.

A counter electrode application and solar cell efficiency measurement were carried out as described in Example 1, and long-term stability measurement was only carried out at room temperature. The results are shown in the following Table 2.

TABLE 2

| Storage | Storage | J_{SC} | | | |
|---|---|---|---|---|---|
| Temperature | Time | (mA/cm²) | V_{OC} (V) | FF (%) | η (%) |
| Room | 0 hours | 13.5 | 0.85 | 60.4 | 6.9 |
| Temperature | 500 hours | 11.8 | 0.82 | 60.0 | 5.8 |
| | 1000 hours | 10.4 | 0.83 | 59.8 | 5.2 |

### Example 3

2,2′,7,7′-tetrakis(diphenylamino)-9.9′-spirobifluorene (spiro-MeOTAD), a hole transport material, was dissolved in a chlorobenzene solvent to have a concentration of about 0.17 M, and as an additive, lithium bis(trifluoromethanesulfonyl)imide (Li-TFSI) and a trimer linking 3 pyridines were dissolved therein to have concentrations of about 21 mM and about 0.05 M, respectively, for about 1 hour at a temperature of about 60° C. Therefore, a uniform and transparent solution was prepared.

The preparation of a working electrode and a counter electrode was carried out as described in Example 1, and efficiency measurement and long-term stability tests of the solar cell device were also carried out as described in Example 1. The results are shown in the following Table 3 and FIG. 1.

TABLE 3

| Storage | Storage | J_{SC} | | | |
|---|---|---|---|---|---|
| Temperature | Time | (mA/cm²) | V_{OC} (V) | FF (%) | η (%) |
| Room | 0 hours | 8.8 | 0.78 | 49.7 | 3.4 |
| Temperature | 500 hours | 9.0 | 0.80 | 45.7 | 3.3 |
| | 1000 hours | 9.1 | 0.81 | 45.2 | 3.4 |
| 70 °C. | 0 hours | 8.8 | 0.78 | 49.7 | 3.4 |
| | 500 hours | 8.8 | 0.81 | 48.8 | 3.5 |
| | 1000 hours | 8.7 | 0.79 | 50.4 | 3.5 |

### Example 4

2,2′,7,7′-tetrakis(diphenylamino)-9.9′-spirobifluorene (spiro-MeOTAD), a hole transport material, was dissolved in a chlorobenzene solvent to have a concentration of about 0.17 M, and as an additive, lithium bis(trifluoromethanesulfonyl)imide (Li-TFSI) and a tetramer linking 4 pyridines were dissolved therein to have concentrations of about 21 mM and about 0.05 M, respectively, for about 1 hour at a temperature of about 60° C. Therefore, a uniform and transparent solution was prepared.

The preparation of a working electrode and a counter electrode was carried out as described in Example 1, and efficiency measurement and long-term stability tests of the solar cell device were also carried out as described in Example 1. The results are shown in the following Table 4.

TABLE 4

| Storage | Storage | J_{SC} | | | |
|---|---|---|---|---|---|
| Temperature | Time | (mA/cm²) | V_{OC} (V) | FF (%) | η (%) |
| Room | 0 hours | 8.2 | 0.75 | 40.7 | 2.5 |
| Temperature | 500 hours | 8.5 | 0.78 | 40.9 | 2.7 |
| | 1000 hours | 8.5 | 0.77 | 39.4 | 2.6 |
| 70 °C. | 0 hours | 8.2 | 0.75 | 40.7 | 2.5 |
| | 500 hours | 8.4 | 0.77 | 40.8 | 2.6 |
| | 1000 hours | 8.4 | 0.78 | 38.5 | 2.5 |

### Example 5

2,2′,7,7′-tetrakis(diphenylamino)-9.9′-spirobifluorene (spiro-MeOTAD), a hole transport material, was dissolved in a chlorobenzene solvent to have a concentration of about 0.17 M, and as an additive, lithium bis(trifluoromethanesulfonyl)imide (Li-TFSI) was dissolved therein to have a concentration of about 21 mM, and a dimer linking 2 pyridines was dissolved therein increasing the concentration from about 0.11 M (Sample 1) to about 0.2 M (Sample 2) and about 0.3 M (Sample 3) for about 1 hour at a temperature of about 60° C. Therefore, a uniform and transparent solution was prepared.

The preparation of a working electrode and a counter electrode was carried out as described in Example 1, and efficiency measurement of the solar cell device was carried out once immediately after manufacturing the cell. The results are shown in the following Table 5.

TABLE 5

| Sample | J_{SC}(mA/cm²) | V_{OC}(V) | FF(%) | η(%) |
|---|---|---|---|---|
| Sample 1 | 9.5 | 0.76 | 54.8 | 4.0 |
| Sample 2 | 9.2 | 0.78 | 55.2 | 4.0 |
| Sample 3 | 9.1 | 0.82 | 58.4 | 4.4 |

### Example 6

Poly-3-hexylthiophene (P3HT), a hole transport material, was dissolved in a 1,2-dichlorobenzene solvent to have a concentration of about 15 mg/ml, and as an additive, lithium bis(trifluoromethanesulfonyl)imide (Li-TFSI) and a dimer linking 2 pyridines were dissolved therein to have concentrations of about 10.5 mM and about 0.05 M, respectively, for about 1 hour at a temperature of about 60° C., resulting in a uniform and transparent solution.

The preparation of a working electrode and a counter electrode was carried out as described in Example 1, and efficiency measurement and long-term stability tests of the solar cell device were also carried out as described in Example 1. The results are shown in the following Table 6.

TABLE 6

| Storage | Storage | J_{SC} | | | |
|---|---|---|---|---|---|
| Temperature | Time | (mA/cm²) | V_{OC} (V) | FF (%) | η (%) |
| Room | 0 hours | 9.3 | 0.58 | 62.4 | 3.4 |
| Temperature | 500 hours | 9.0 | 0.56 | 62.0 | 3.1 |
| | 1000 hours | 8.7 | 0.56 | 59.8 | 2.9 |
| 70 °C. | 0 hours | 9.3 | 0.58 | 62.4 | 3.4 |
| | 500 hours | 8.8 | 0.56 | 59.5 | 2.9 |
| | 1000 hours | 8.5 | 0.57 | 55.5 | 2.7 |

### Example 7

2,2′,7,7′-tetrakis(diphenylamino)-9.9′-spirobifluorene (spiro-MeOTAD), a hole transport material, was dissolved in a chlorobenzene solvent to have a concentration of about 0.17 M, and as an additive, lithium bis(trifluoromethanesulfonyl)imide (Li-TFSI) was dissolved therein increasing the concentration to about 5 mM (Sample 4), about 10 mM (Sample 5), about 21 mM (Sample 6) and about 30 mM (Sample 7), and a dimer linking 2 pyridines was dissolved therein to have a concentration of about 0.11 M, for about 1 hour at a temperature of about 60° C., resulting in a uniform and transparent solution.

The preparation of a working electrode and a counter electrode was carried out as described in Example 1, and efficiency measurement of the solar cell device was carried out once immediately after manufacturing the cell. The results are shown in the following Table 7.

TABLE 7

| Sample | J_{SC}(mA/cm²) | V_{OC}(V) | FF(%) | η(%) |
|---|---|---|---|---|
| Sample 1 | 8.3 | 0.83 | 61.4 | 4.2 |
| Sample 2 | 8.5 | 0.81 | 60.7 | 4.2 |
| Sample 3 | 9.0 | 0.78 | 55.4 | 3.9 |
| Sample 4 | 9.5 | 0.76 | 54.8 | 4.0 |

### Comparative Example 1

2,2′,7,7′-tetrakis(diphenylamino)-9.9′-spirobifluorene (spiro-MeOTAD), a hole transport material, was dissolved in a 1,2-dichlorobenzene solvent to have a concentration of about 0.17 M, and as an additive, lithium bis(trifluoromethanesulfonyl)imide (Li-TFSI) and tert-butylpyridine were dissolved therein to have concentrations of about 21 mM and about 0.11 M, respectively, for about 1 hour at a temperature of about 60° C., resulting in a uniform and transparent solution.

The preparation of a working electrode and a counter electrode was carried as described in Example 1, and efficiency measurement and long-term stability tests of the solar cell device were also carried out as described in Example 1. The results are compared and shown in the following Table 8 and FIG. 1.

TABLE 8

| Storage | Storage | J_{SC} | | | |
|---|---|---|---|---|---|
| Temperature | Time | (mA/cm²) | V_{OC} (V) | FF (%) | η (%) |
| Room | 0 hours | 10.3 | 0.77 | 59.8 | 4.7 |
| Temperature | 500 hours | 9.4 | 0.58 | 52.1 | 2.8 |
| | 1000 hours | 7.9 | 0.44 | 43.5 | 1.5 |
| 70 °C. | 0 hours | 10.3 | 0.77 | 59.8 | 4.7 |
| | 500 hours | 6.5 | 0.47 | 40.8 | 1.2 |
| | 1000 hours | 3.4 | 0.38 | 30.3 | 0.4 |

According to various exemplary embodiments, the solid-state dye-sensitized solar cell may obtain improved long-term stability containing a pyridine-based additive as well as initial efficiency, and further, the solid-state dye-sensitized solar cell that is manufactured using a solution process may be widely used as large-area flexible solar cells and the like.

The invention has been described in detail with reference to exemplary embodiments thereof. However, it will be appreciated by those skilled in the art that changes may be made in these embodiments without departing from the principles and spirit of the invention, the scope of which is defined in the appended claims and their equivalents.

What is claimed is:

1. A solid-state dye-sensitized solar cell with improved long-term stability, comprising:
one or more pyridine compounds independently selected from compounds of the following Chemical Formulae 1 to 3: 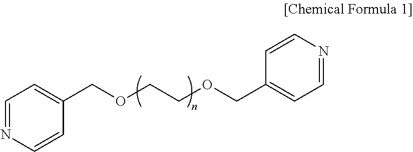
wherein, in the Chemical Formula 1, n is a natural number ranging from 1 to 20; 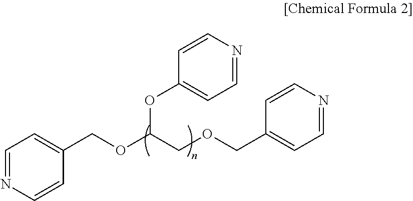
wherein, in the Chemical Formula 2, n is a natural number ranging from 1 to 10; and

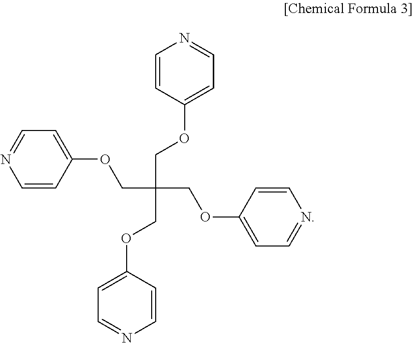 [SMILES: c1cc(OCC(COc2ccncc2)(COc2ccncc2)COc2ccncc2)ccn1]

2. The solar cell of claim 1, which has a structure comprising:
a working electrode configured to be a first electrode;
a second electrode configured to be provided opposite to the first electrode;
an oxide layer configured to be formed between the first electrode and the second electrode and include a light absorbing layer; and
a hole transport layer configured to be adjacent to the oxide layer and contain a hole transport material and one or more pyridine compounds selected from the compound of the Chemical Formulae 1 to 3 as an additive.

3. The solar cell of claim 2, wherein the one or more pyridine compounds selected from the compounds of the Chemical Formulae 1 to 3 form a solid-state of the hole transport layer as being mixed with the hole transport material.

4. The solar cell of claim 2, wherein the one or more pyridine compounds selected from the compounds of the Chemical Formulae 1 to 3 are included in concentrations of about 0.05 to 0.5 M based on the hole transport material in the hole transport layer.

5. The solar cell of claim 2, wherein the pyridine compound of the Chemical Formula 1 is included in a concentration of about 0.1 to 0.3 M based on the hole transport material in the hole transport layer.

6. The solar cell of claim 2, wherein the pyridine compound of the Chemical Formula 2 is a trimer compound of the following Chemical Formulae 2a and is included in a concentration of about 0.05 to 0.2 M based on the hole transport material in the hole transport layer:

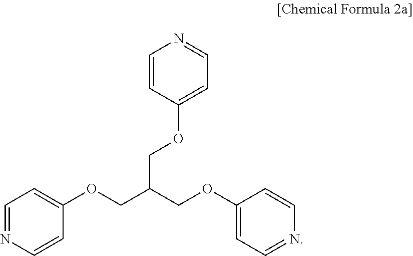 [SMILES: c1cc(OCC(COc2ccncc2)COc2ccncc2)ccn1]

7. The solar cell of claim 2, wherein the pyridine compound of the Chemical Formula 3 is included in a concentration of about 0.05 to 0.1 M based on the hole transport material in the hole transport layer.

8. The solar cell of claim 2, wherein the hole transport layer includes one or more pyridine compounds selected from the compounds of Chemical Formulae 1 to 3; and one or more hole transport materials selected from the group selected from poly-hexylthiophene (P3HT), 2,2′,7,7′-tetrakis(diphenylamino)-9.9′-spirobifluorene (Spiro-MeOTAD), poly[2-methoxy-5-(2-ethylhexyloxy)-1,4-phenylenevinylene] (MEHPPV), and poly[2,5-bis(2-decyldodecyl)pyrrolo[3,4-c]pyrrole-1,4(2H,5H)-dione-(E)-1,2-di(2,2′-bithiophen-5-yl)ethene] (PDPPDBTE).

9. The solar cell of claim 8, further comprising:
lithium bis(trifluoromethanesulfonyl) imide (Li-TFSI) in a concentration of about 5 to 30 mM based on the hole transport material.

10. The solar cell of claim 2, wherein the first electrode includes one or more materials selected from the group consisting of indium-tin oxide (ITO), Fluorine-doped tin oxide (FTO), ZnO/Ga₂O₃, ZnO/Al₂O₃ and SnO₂—Sb₂O₃.

11. The solar cell of claim 2, wherein the light absorbing layer includes a porous oxide and a light absorbing dye, and the light absorbing dye is adsorbed to the porous oxide.

12. The solar cell of claim 11, the porous oxide is titanium oxide and the light absorbing dye is a ruthenium-based dye.

13. The solar cell of claim 2, wherein the second electrode is a counter electrode and includes gold, silver and platinum.

14. A mixed solution of a hole transport material for a solar cell, wherein one or more pyridine compounds independently selected from compounds of the following Chemical Formulae 1 to 3 are mixed to the hole transport material as an additive: 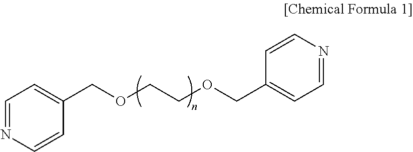
wherein, in the Chemical Formula 1, n is a natural number ranging from 1 to 20; 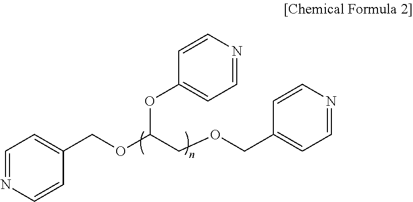
wherein, in the Chemical Formula 2, n is a natural number ranging from 1 to 10; and

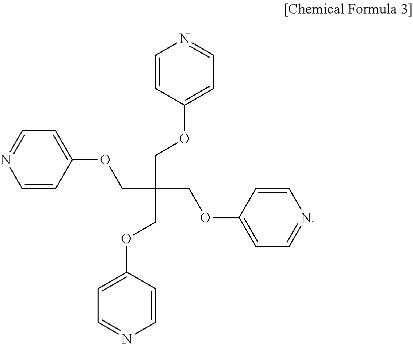 [SMILES: c1cc(OCC(COc2ccncc2)(COc2ccncc2)COc2ccncc2)ccn1]

15. The mixed solution of claim 14, wherein one or more pyridine compounds selected from the compounds of the following Chemical Formulae 1a, 2a and 3 are included in concentrations of about 0.05 to 0.5 M based on the hole transport material:

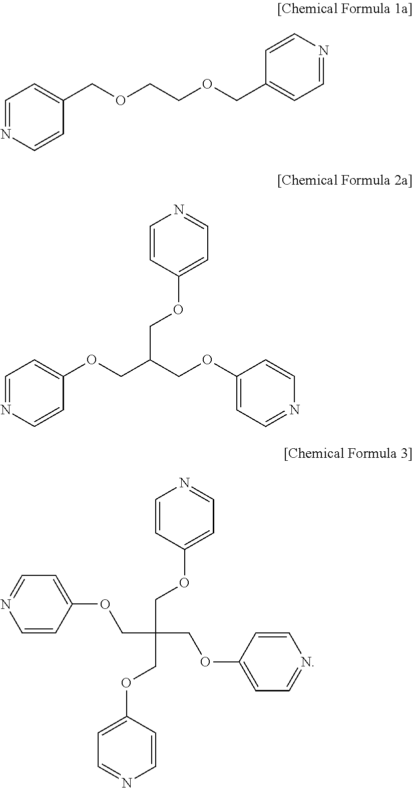 [SMILES: c1cc(COCCOCc2ccncc2)ccn1 ; c1cc(OCC(COc2ccncc2)COc2ccncc2)ccn1 ; c1cc(OCC(COc2ccncc2)(COc2ccncc2)COc2ccncc2)ccn1]

16. The mixed solution of claim 14, comprising:
one or more pyridine compounds selected from the compounds of the following Chemical Formulae 1a, 2a and 3;
one or more hole transport materials selected from the group consisting of poly-hexylthiophene (P3HT), 2,2′,7,7′-tetrakis(diphenylamino)-9.9′-spirobifluorene (Spiro-MeOTAD), poly[2-methoxy-5-(2-ethylhexyloxy)-1,4-phenylenevinylene] (MEHPPV) and poly[2,5-bis(2-decyldodecyl)pyrrolo[3,4-c]pyrrole-1,4(2H,5H)-dione-(E)-1,2-di(2,2′-bithiophen-5-yl)ethene] (PDPPDBTE); and
lithium bis(trifluoromethanesulfonyl) imide (Li-TFSI) in a concentration of 5 to 30 mM based on the hole transport material:

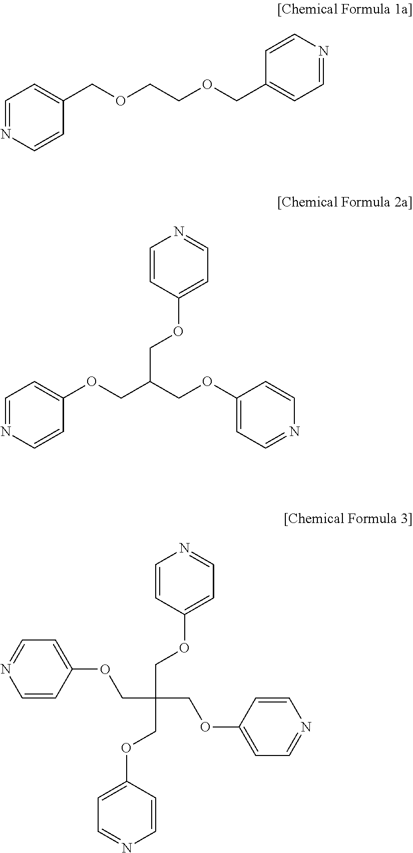 [SMILES: c1cc(COCCOCc2ccncc2)ccn1 ; c1cc(OCC(COc2ccncc2)COc2ccncc2)ccn1 ; c1cc(OCC(COc2ccncc2)(COc2ccncc2)COc2ccncc2)ccn1]

17. A method for manufacturing a solid dye-sensitive solar cell, comprising:
preparing a mixed solution of a hole transport material by dissolving a hole transport material in a solvent and adding one or more pyridine compounds selected from compounds of Chemical Formulae 1 to 3 thereto;
forming an inorganic oxide dense layer on a working electrode;
forming a light absorbing layer that includes a porous oxide and a light absorbing dye on the inorganic oxide dense layer;
forming a hole transport layer by applying the mixed solution on the light absorbing layer; and
applying a counter electrode on the hole transport layer.

18. The method for manufacturing a solar cell of claim 17, wherein, during forming the light absorbing layer on the inorganic oxide dense layer, the method further comprises adsorbing the light absorbing dye to the porous oxide.

19. A vehicle that comprising a solar-cell of claim 1.
